(19) United States
(12) Patent Application Publication
(10) Pub. No.: US 2011/0273220 A1
(43) Pub. Date: Nov. 10, 2011

(54) OPTIMAL MOSFET DRIVER CIRCUIT FOR REDUCING ELECTROMAGNETIC INTERFERENCE AND NOISE

(76) Inventors: Feng LIN, Camarillo, CA (US); Chin Chang, Agoura Hills, CA (US)

(21) Appl. No.: 13/100,168

(22) Filed: May 3, 2011

Related U.S. Application Data
(60) Provisional application No. 61/331,156, filed on May 4, 2010.

(51) Int. Cl. H03K 17/04

(52) U.S. Cl. 327/374

(57) ABSTRACT

A system and method of controlling the primary switching FET turn-on and turn-off profiles in a switching power converter suppresses voltage and current spikes, reduces power consumption, and reduces system switching time. A combination of fast and slow shunt circuits is used to control current flow through the primary switching FET. The FET switching rate is slowed during the period of maximum current change to limit the magnitude of switching spikes and is allowed to proceed rapidly at other times to reduce switching time and power consumption.

### RELATED APPLICATION DATA

This application claims priority pursuant to 35 U.S.C. §119(e) to U.S. provisional patent application Ser. No. 61/331,156, filed May 4, 2010, the subject matter of which is incorporated by reference herein in its entirety.

### BACKGROUND OF THE INVENTION

1. Field of the Invention

The invention relates generally to the field of switching power converters, and more particularly, to drive circuits for MOSFETs that minimize switching power loss while simultaneously reducing switching time and improving system efficiency.

2. Description of Related Art

In a switching power converter, it is known in the art that parasitic inductances and capacitances of circuit elements can produce resonances that result in large voltage spikes and ringing when the primary MOSFET is switched off. These voltage spikes can lead to avalanche breakdown of the MOSFET insulator, eventually damaging it. It is therefore necessary to reduce the magnitude of these voltage spikes and suppress the ringing.

It is common in the art to use a snubbing circuit for this purpose. A snubbing circuit typically includes a diode, a capacitor, and a resistor. FIGS. 1A and 1B depict typical snubbing configurations. The circuit in FIG. 1A is an exemplary clamping configuration that includes a parallel resistor 102 and capacitor 104 in series with a diode 106. This circuit limits how high the voltage can rise at the drain of the switching MOSFET 110. The circuit in FIG. 1B is an exemplary rate-control snubber that includes a parallel diode 156 and resistor 152 in series with a capacitor 154. This circuit limits the rate at which the drain voltage of the MOSFET 160 can rise when it is shut off.

A disadvantage of using a snubbing circuit is that it increases the power loss of the circuit and thus reduces the power conversion efficiency as power is dissipated in the snubber diode and resistor. In addition, the snubber necessarily slows the turn-off time of the MOSFET. In a high-frequency power converter, this can introduce significant dead time, dramatically reducing system efficiency. Accordingly, it would be advantageous to actively control the turn-off rate of the MOSFET in order to provide the same level of voltage spike suppression while simultaneously reducing power loss and limiting the increase in system dead time.

### SUMMARY OF THE INVENTION

Embodiments of the present invention are directed to controlling the turn-on and turn-off profiles of the primary switching FET assembly of a power converter in order to minimize voltage and current spikes while also reducing dead time and power consumption.

A first embodiment of a switching control system for a power converter includes an input interface to a primary power source, an output interface to a load, and a primary inductor assembly operatively connected between the input interface to the primary power source and the output interface to the load. It further includes a primary switching FET assembly that is operatively connected to the primary inductor assembly and configured to regulate the power delivered to the load. The embodiment further includes a shunt control assembly operable to control the primary FET switching assembly. The shunt control assembly includes a slow shunt assembly and a fast shunt assembly. The slow shunt assembly includes a slow shunt resistor and a slow shunt switch configured such that the slow shunt switch can selectively connect the slow shunt resistor between the base of the primary FET switching assembly and ground. The fast shunt assembly similarly includes a fast shunt resistor and a fast shunt switch configured to selectively connect the fast shunt resistor between the primary FET switching assembly and ground. In a preferred embodiment, the slow shunt resistor has a value of approximately 1 ohm and the fast shunt resistor has a value of approximately 0.1 milliohms. However, other values are possible and would fall within the scope and spirit of the present invention.

An embodiment of the present invention further includes a control circuit that controls the fast shunt circuit and the slow shunt circuit in order to control the turn-off profile of the primary FET switching assembly. In one embodiment, the control circuit closes the fast shunt circuit and the slow shunt circuit during a first time interval such that the primary switching FET is driven rapidly toward an off state. During a second time interval, the fast shunt switch is opened such that the primary switching FET is driven more slowly toward the off state, and during a third time interval, the fast shunt switch is closed again to drive the primary FET the rest of the way off at a rapid rate. The time intervals are adjusted to reduce voltage and current switching spikes while at the same time to reduce power consumption and dead time.

In some embodiments, the duration of the first, second, and third time intervals are set by timing circuits that apply pre-set time intervals suitably chosen to reduce power consumption and dead time while also suppressing current and voltage spikes. In other embodiments, the current through the primary FET is measured and used to trigger the timing of the first, second, and third time intervals.

In one embodiment, a second fast shunt switch is connected in parallel with the first fast shunt switch such that closing either one will connect the fast shunt resistor to the base of the primary switching FET. In such an embodiment, the first fast shunt switch may be closed during the first time interval and the second may be closed during the third time interval to achieve the operation described above.

It should be noted that because the slow shunt resistor is preferably significantly larger than the fast shunt resistor, opening and closing the slow shunt switch does not appreciably change the primary FET turn-off rate when the fast shunt resistor is connected to the base of the primary FET. In such a situation, opening the slow shunt switch may be functionally equivalent to closing the slow shunt switch because it will primarily be the fast shunt switch that controls the operation of the device. Such a system also falls within the scope and spirit of the present invention.

In another embodiment of the invention, the turn-on rate of the primary switching FET assembly may be controlled in the same manner. Such an embodiment includes a fast turn-on assembly comprising a fast turn-on resistor and a fast turn-on switch that is configured to selectively connect the gate of the primary FET switching assembly to an auxiliary power supply. It further includes a slow turn-on resistor and slow turn-on switch that is configured to selectively connect the gate of the primary FET switching assembly to an auxiliary power supply. In some embodiments, the auxiliary power supply may be the primary power supply of the converter, or it may be a separate power supply. In an embodiment of the invention, the switching control system is operable to close the fast turn-on switch and the slow turn-on switch during a first turn-on time interval such that the primary switching FET assembly is driven toward an on state at a fast rate. During a second turn-on time interval, the fast turn-on switch is opened such that the primary FET is driven toward the on state at a slower rate. During a third turn-on time interval, the fast turn-on switch is again closed in order to drive the FET rapidly to the on state. In a preferred embodiment, the fast turn-on resistor has a value of approximately 0.1 milliohm and the slow turn-on resistor has a value of approximately 1 ohm. Other values are possible and would fall within the scope and spirit of the present invention.

Other embodiments, modifications, and adaptations of the disclosed invention are also possible and will be evident to one of ordinary skill in the art by examination of the detailed description and the attached sheets of drawings, which will first be described briefly.

### BRIEF DESCRIPTION OF THE DRAWINGS

FIGS. 1A and 1B depict resistor-capacitor-diode snubber circuits, typical of the prior art;

FIG. 2 is a conceptual block diagram of a power switching circuit typical of a switching power converter;

FIG. 3 depicts the behavior of the MOSFET gate voltage, the MOSFET drain current, and the MOSFET drain voltage during a turn-off event;

FIG. 4 is block diagram of a switching circuit in accordance with an embodiment of the present invention;

FIG. 5 is a simulated waveform showing circuit behavior in the case of no waveform snubbing;

FIG. 6 depicts the simulated power loss profile of a switching circuit without waveform snubbing;

FIG. 7 depicts a simulated waveform showing circuit behavior in the case of a typical snubbing circuit;

FIG. 8 depicts the simulated power loss profile of a switching circuit with a typical snubbing circuit;

FIG. 9 depicts a simulated waveform showing circuit behavior in the case of a circuit with a controlled turn-off profile in accordance with an embodiment of the present invention; and

FIG. 10 depicts the simulated power loss profile of a switching circuit with a controlled turn-off profile in accordance with an embodiment of the present invention.

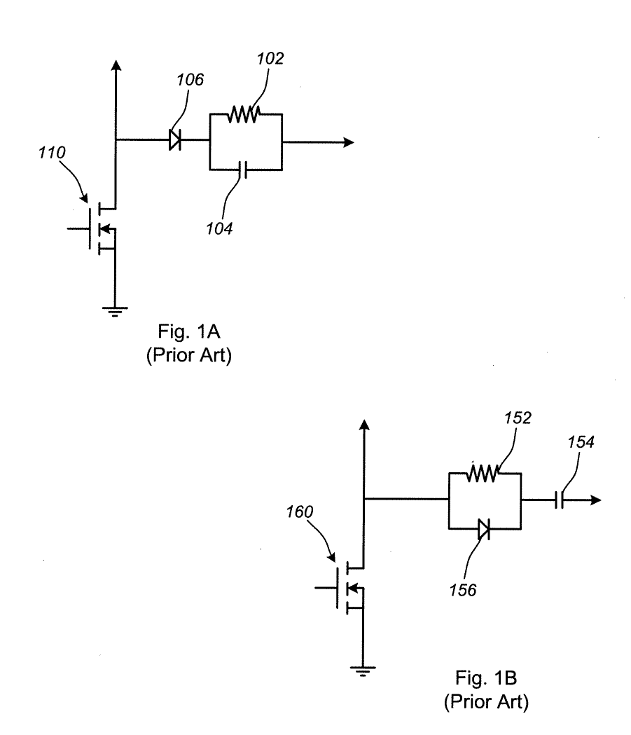

### DETAILED DESCRIPTION OF THE PREFERRED EMBODIMENT

An embodiment of present invention controls the turn-off profile of a MOSFET or similar device in order to reduce voltage spikes and electromagnetic interference (EMI) while at the same time limiting power losses and retaining relatively fast switching speeds. For example, the table below compares three simulations of a 30-Volt MOSFET switching circuit. Case one shows a fast turn off of a MOSFET in a circuit with no snubber. Case two shows a slow turn off for a circuit in which a snubber typical of the prior art is used. Case three shows a controlled MOSFET turn off in a circuit in accordance with an embodiment of the present invention.

| | Case 1 | | Case 2 | | Case 3 | |
|---|---|---|---|---|---|---|
| | No | | Typical | | Embodiment of the | |
| | snubber | | snubber | | present invention | |
| Spike (V) | 51 | V | 31 | V | 31.5 | V |
| Switching power | 1.61 | W | 3.1 | W | 2.3 | W |
| loss (W) | | | | | | |
| Switching time (ns) | 22.7 | ns | 186 | ns | 50 | ns |

As can be seen from the table above, the use of a snubber can significantly reduce the magnitude of the voltage spike from 51 V to 31 V. However, it also increases the switching power loss of the system from 1.61 W to 3.1 W. By comparison, an embodiment of the present invention achieves nearly the same level of voltage spike suppression, but only increases the power loss to 2.3 W. The conventional snubber circuit thus dissipates 35% more power than the controlled turn-off system in accordance with the present invention.

Similarly, the typical snubber circuit produces a dramatic increase in turn-off time, increasing the switching time from 22.7 ns to 186 ns. By contrast, an embodiment of the present invention increases the switching time to only 50 ns. For high-frequency power conversion applications, this increase in turn-off time can be significant and may dramatically reduce system efficiency.

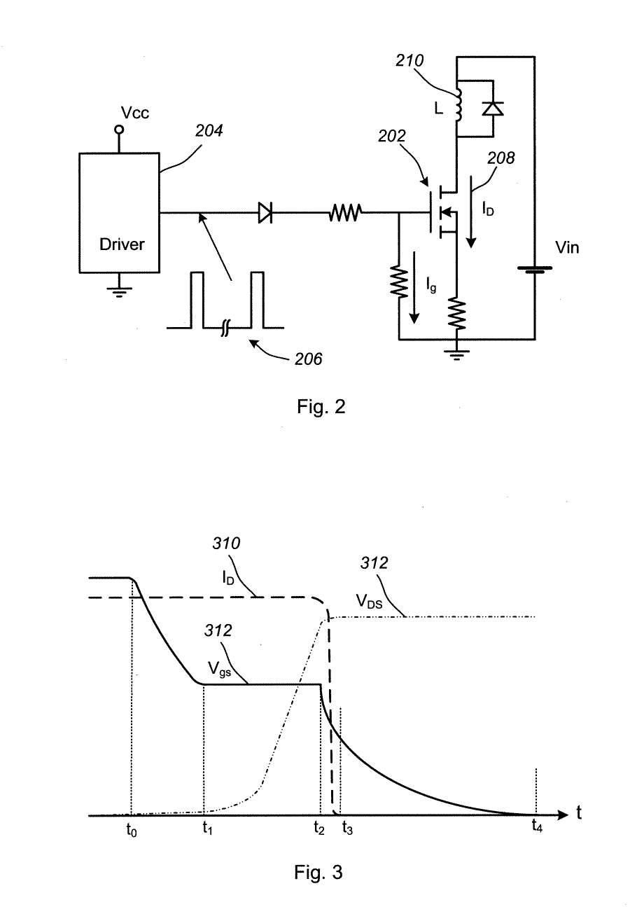

FIGS. 2 and 3 are a conceptual circuit diagram and a waveform plot, respectively, illustrating a MOSFET 202 turning off. The drive waveform 206 is applied to the gate of MOSFET 202. The trailing edge of each pulse turns off the MOSFET 202. When the MOSFET 202 is on, current 208 (I_{D}) passes through it. This current is also plotted as trace 310 in FIG. 3. At this time, the gate-source voltage (V_{gs}) across the MOSFET 202 is high, as shown in trace 312 in FIG. 3. At time t₀, the drive waveform is turned off, and V_{gs} begins to drop until it hits a plateau between times t₁ and t₂ as the magnetic field across inductor 210 (L) collapses. The current I_{D} through the MOSFET finally collapses between times t₂ and t₃, as shown in FIG. 3, and the drain-source voltage 312 (V_{DS}) becomes equal to Vin. The gate-source voltage 312 (V_{gs}) continues to decay until it reaches essentially zero at time t₄.

In simple terms, an embodiment of the present invention controls the turn-off rate of the MOSFET during the time regimes shown in FIG. 3. In the initial period from t₀ up through t₂, the MOSFET is turned off as rapidly as possible. Then, during the interval t₂ to t₃, when the MOSFET current is collapsing, the turn-off rate is slowed to eliminate the high-frequency components of the change in current that would otherwise cause large voltage spikes and electromagnetic emissions. Then, after time t₃, the turn-off rate is again sped up. By slowing down only the critical portion of the waveform where the largest current change is taking place, the present invention achieves suppression of drain voltage spikes without a large increase in the turn off time.

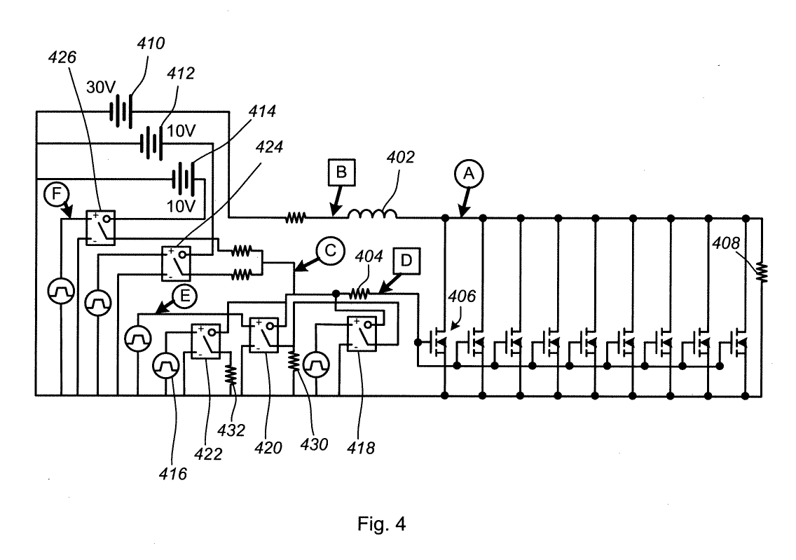

FIG. 4 is a schematic diagram of an embodiment of the present invention that achieves the above-described rate control. MOSFET 406 is a primary switching FET and is depicted as nine MOSFETs in a parallel configuration to maximize current-carrying capability and limit on resistance. The 30-volt battery 410 is the primary power source, and two auxiliary batteries 412 and 414 are employed to achieve the switching rate control. Of course, other configurations of power sources are possible, as would be appreciated by one skilled in the art.

When MOSFET 406 is on, the primary current runs through the inductor 402. The symbol “B” indicates a current probe positioned at the inductor 402 to measure the primary current. The symbol “A” indicates a voltage probe measuring the drain voltage of the switching MOSFET. The symbol “D” indicates a current probe measuring the gate current of the MOSFET, and symbol “C” indicates the gate voltage. Switches 418, 420, 422, 424, and 426 affect the bias voltage applied to the gate of switching MOSFET 406 and are used to control the turn off profile according to an embodiment of the present invention.

In a particular embodiment of the invention described with reference to FIG. 4, circuits 418, 420, and 422 simulate internal driver circuits for switching off the MOSFET 406. Each of these circuits shunts the MOSFET gate voltage to drive it to an off state. Resistor 432 is chosen to have a relatively large value, such as 1 Ohm, while resistor 430 is selected to have a very small value, such as 0.0001 Ohm. To begin the shut-off procedure, switches 420 and 422 are closed to drive the MOSFET 406 toward the off state. After a short time delay of approximately 8 ns in this embodiment, switch 420 is opened. Because the resistor 430 coupled to switch 420 is very small compared to resistor 432 coupled to switch 422, the gate shunt drops dramatically with the large increase in resistance. This slows the turn-off profile of the MOSFET 406 to avoid a large current switching spike. Once the MOSFET current has dropped sufficiently, switch 418 is closed. Resistor 404, coupled to switch 418, has the same low value as resistor 430. It thus provides a very low resistance path that shunts the remaining gate voltage as quickly as possible to minimize total power loss. Switches 424 and 426 operate in the same fashion, but for the MOSFET turn-on function. Switching spikes are thus minimized while keeping power loss low. Of course, the circuit component values and timing parameters are exemplary only and may be modified without departing from the scope and spirit of the present invention.

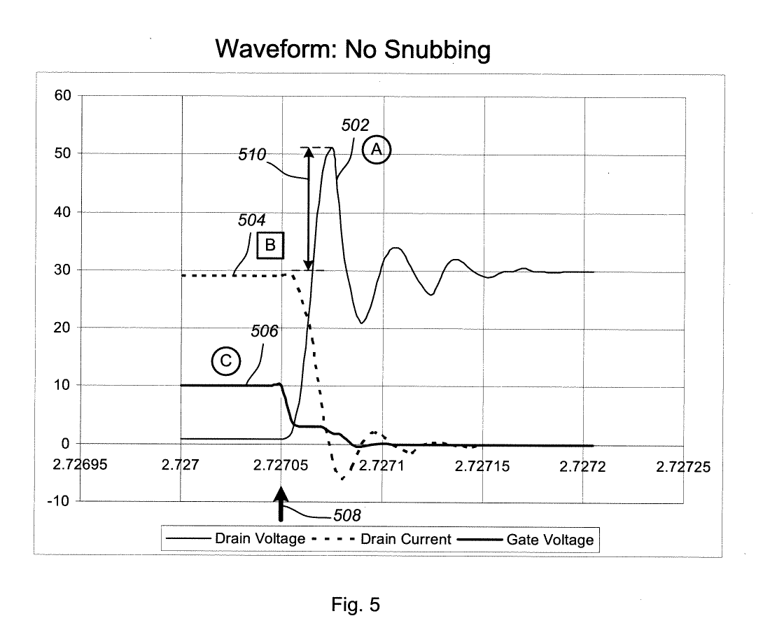

FIG. 5 shows the simulated results of turning off the MOSFET 406 depicted in FIG. 4 without using any snubbing and without applying the turn-off control contemplated by the present invention. Trace 506, labeled “C” depicts the gate voltage during shutdown, which is initiated at the time indicated by arrow 508. As previously discussed, the gate voltage drops quickly initially and then reaches a plateau during the time the magnetic field through the inductor 402 collapses. The gate voltage then reaches zero, fully shutting off MOSFET 406. The current through the MOSFET (and inductor 402) is depicted by trace 504, labeled “B.” This current drops quite rapidly, keeping the power loss relatively low. But as a consequence, the drain voltage, depicted at trace 502 and labeled “A” exhibits significant ringing, rising to over 50 volts. This overshoot, depicted at 510, reaches 21 volts in this simulation, and can potentially damage the switching MOSFETs.

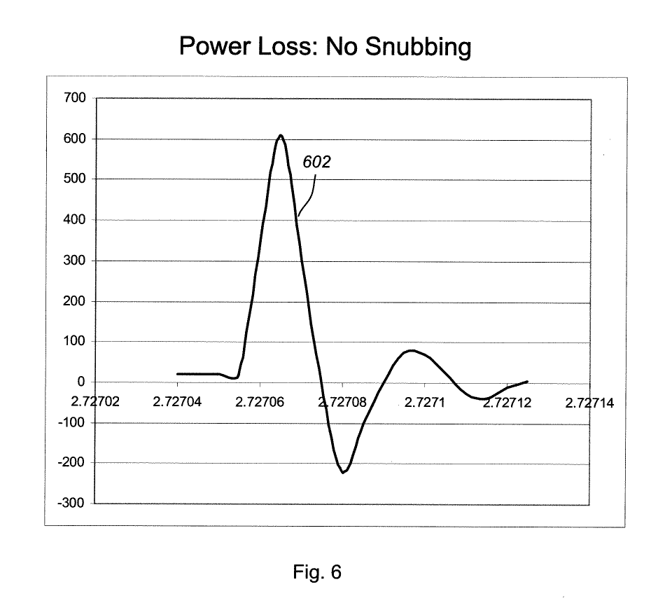

The power loss represented by switching without snubbing and without active turn-off control is shown in FIG. 6 at trace 602. The fast turn off has the advantage of low power loss, amounting to only 1.61 Watts in this simulation, but has a cost of potential damage to the MOSFET, as described above.

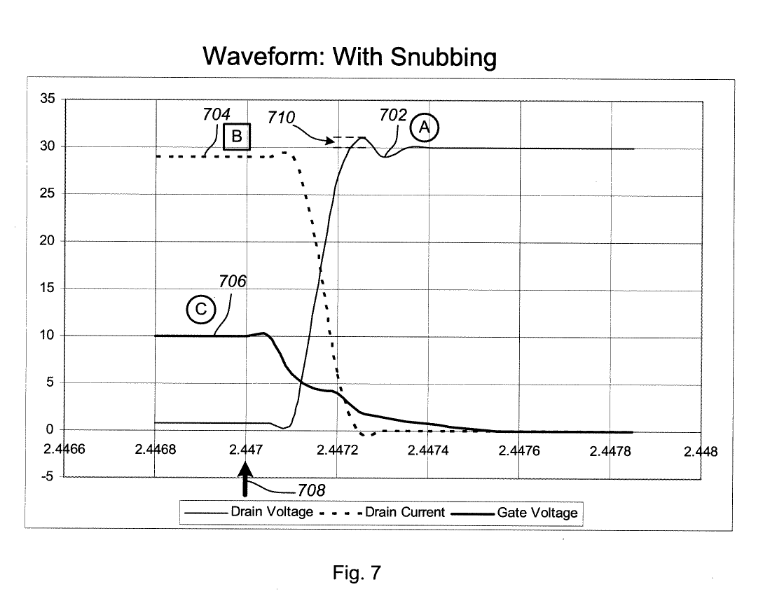

FIG. 7 depicts a simulated turn-off waveform using a traditional snubbing circuit. It can bee seen that the gate voltage “C” at trace 706 falls more slowly, taking more time to turn off the MOSFET current at trace 704. This greatly reduces the drain voltage overshoot shown at trace 702, labeled “A.” The magnitude of the overshoot 710 in this simulation is only about one volt, illustrating the effectiveness of the snubber.

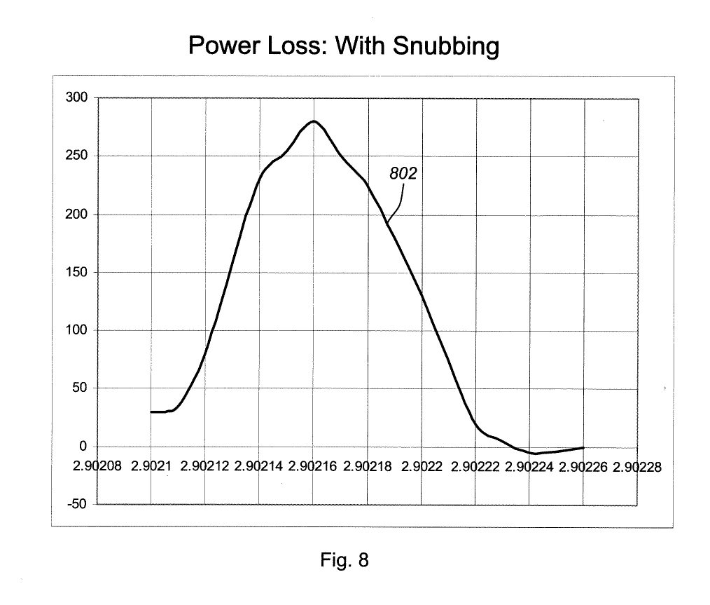

However, this method also greatly increases the power loss, as shown in FIG. 8 at trace 802. Power is lost during the slow turn-off event, resulting in nearly doubling the power loss to 3.1 Watts.

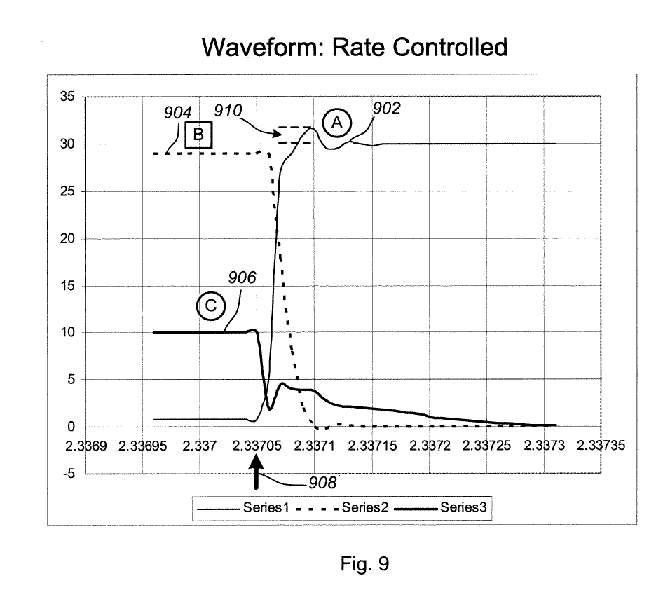

FIG. 9 depicts a simulation of a turn-off event performed in accordance with an embodiment of the present invention. In this case, the gate turn-off voltage shown at trace 906, labeled “C” is actively controlled using the network of switches shown in FIG. 4 as elements 418, 420, 422, 424, and 426. In this manner, the MOSFET current shown at trace 904, labeled “B” is rapidly brought to zero in a controlled manner, leading to very little overshoot of the MOSFET drain voltage, shown at trace 902, labeled “A.” In fact, the overshoot 910 in this embodiment is only about 1.5 V, or just slightly more than in the case of the snubber shown in FIG. 7.

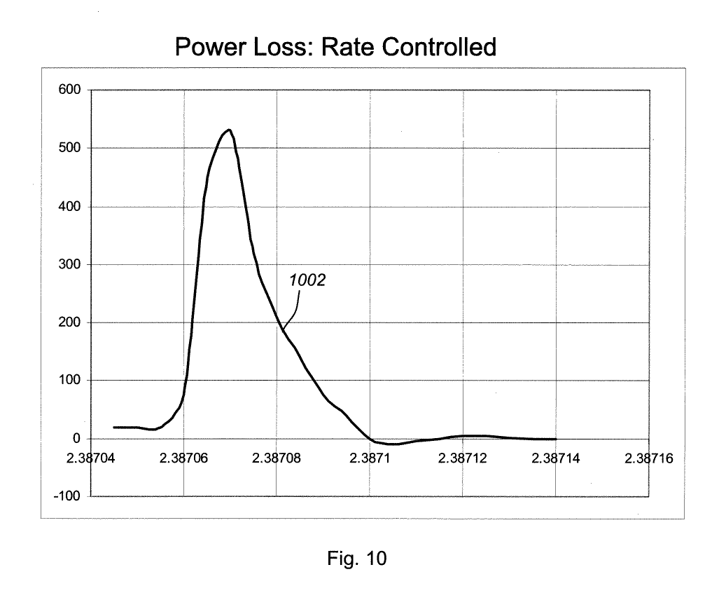

In addition, the controlled turn-off profile achieves a more rapid turn-off of the MOSFET and results in reduced power loss, as shown at trace 1002 depicted in FIG. 10. In fact, the power loss in this case is only 2.3 Watts. This compares favorably to the power loss induced by the snubbing circuit, which is 35% higher.

Thus, the invention achieves a faster turn-off profile than the traditional slow snubbing circuit, allowing for reduced turn-off time and lower power consumption while at the same time protecting the MOSFET from large overvoltage spikes that may cause damage and excessive noise in electronic systems. While the foregoing discussion of the invention focused on the application of a controlled switch in the context of a MOSFET for a switching power converter, it can be applied more generally to other fast switching systems. Those skilled in the art will recognize additional variations and applications of the present invention, and such variations would also fall within the scope and spirit of the present invention. The invention is defined by the following claims:

What is claimed is:

1. A switching control system for a power converter comprising:
an input interface to a primary power source;
an output interface to a load;
a primary inductor assembly operatively connected between the input interface to the primary power source and the output interface to the load;
a primary FET switching assembly operatively connected to the primary inductor assembly and configured to regulate the power delivered to the load;
a shunt control assembly operable to control the primary FET switching assembly, wherein the shunt control assembly comprises:
a slow shunt assembly comprising:
a slow shunt switch; and
a slow shunt resistor, wherein the slow shunt switch is configured to selectively electrically connect the slow shunt resistor between a gate of the primary FET switching assembly and ground; and
a fast shunt assembly comprising:
a fast shunt switch; and
a fast shunt resistor, wherein the fast shunt switch is configured to selectively electrically connect the fast shunt resistor between the gate of the primary FET switching assembly and ground; wherein
the fast shunt resistor has a resistance value that is smaller than that of the slow shunt resistor; and
a control circuit configured to regulate a rate at which the primary FET switching assembly conducting current from the primary inductor assembly turns off by selectively operating the slow shunt assembly and the fast shunt assembly.

2. The switching control system of claim 1, wherein:
the fast shunt resistor has a value of approximately 0.1 miliohms; and
the slow shunt resistor has a value of approximately 1 ohm.

3. The switching control system of claim 1, wherein the control circuit is operable to:
close the fast shunt switch during a first time interval to drive the primary FET switching assembly toward an off state at a fast rate;
open the fast shunt switch and close the slow shunt switch during a second time interval to drive the primary FET switching assembly toward an off state at a slower rate; and
close the fast shunt switch during a third time interval to drive the primary FET switching assembly to an off state at a fast rate.

4. The switching control system of claim 1, further comprising a second fast shunt switch connected in parallel with the fast shunt switch and configured to selectively electrically connect the fast shunt resistor between the gate of the primary FET switching assembly and ground; wherein the control circuit is operable to:
close the fast shunt switch during a first time interval to drive the primary FET switching assembly toward an off state at a fast rate;
open the fast shunt switch and close the slow shunt switch during a second time interval to drive the primary FET switching assembly toward an off state at a slower rate; and
close the second fast shunt switch during a third time interval to drive the primary FET switching assembly to an off state at a fast rate.

5. The switching control system of claim 3, further including a timing circuit, wherein:
a duration of the first time interval, a duration of the second time interval, and a duration of a third time interval are determined by the timing circuit.

6. The switching control system of claim 5, wherein the duration of the first time interval is set to be approximately 8 nanoseconds.

7. The switching control system of claim 3, further including a current monitoring system, wherein:
the current monitoring system is configured to measure a current flowing through the primary FET switching assembly; and
the control circuit is further configured to set a duration of the first time interval, a duration of the second time interval, and a duration of a third time interval based on measurements of the current monitoring system.

8. The switching control system of claim 1, further configured to include:
an auxiliary switching power supply;
a slow turn-on assembly comprising:
a slow turn-on switch; and
a slow turn-on resistor, wherein the slow turn-on switch is configured to selectively connect the slow turn-on resistor between the gate of the primary FET switching assembly and the auxiliary switching power supply; and
a fast turn-on assembly comprising:
a fast turn-on switch; and
a fast turn-on resistor, wherein the fast turn-on switch is configured to selectively connect the fast turn-on resistor between the gate of the primary FET switching assembly and the auxiliary switching power supply; wherein
the fast turn-on resistor has a resistance value that is smaller than that of the slow turn-on resistor; and wherein
the control circuit is further configured to regulate a rate at which the primary FET switching assembly conducting current from the primary inductor assembly turns on by selectively operating the slow turn-on assembly and the fast turn-on assembly.

9. The switching control system of claim 8, wherein the control circuit is further operable to:
close the fast turn-on switch during a first turn-on time interval to drive the primary FET switching assembly toward an on state at a fast rate;
open the fast turn-on switch and close the slow turn-on switch during a second turn-on time interval to drive the primary FET switching assembly toward an on state at a slower rate; and
close the fast turn-on switch during a third turn-on time interval to drive the primary FET switching assembly to an on state at a fast rate.

10. The switching control system of claim 8, wherein:
the fast turn-on resistor has a value of approximately 0.1 miliohms; and
the slow turn-on resistor has a value of approximately 1 ohm.

11. The switching control system of claim 8, wherein the auxiliary switching power supply is the primary power source.

12. A switching control system for a power converter comprising:
an input interface to a primary power source;
an output interface to a load;
an auxiliary switching power supply;
a primary inductor assembly operatively connected between the input interface to the primary power source and the output interface to the load;
a primary FET switching assembly operatively connected to the primary inductor assembly and configured to regulate the power delivered to the load;
a shunt control assembly operable to control the primary FET switching assembly, wherein the switching control assembly comprises:
a slow shunt assembly comprising:
a slow shunt switch; and
a slow shunt resistor, wherein the slow shunt switch is configured to selectively electrically connect the slow shunt resistor between a gate of the primary FET switching assembly and ground; and
a fast shunt assembly comprising:
a fast shunt switch; and
a fast shunt resistor, wherein the fast shunt switch is configured to selectively electrically connect the fast shunt resistor between the gate of the primary FET switching assembly and ground; wherein
the fast shunt resistor has a resistance value that is smaller than that of the slow shunt resistor;
a slow turn-on assembly comprising:
a slow turn-on switch; and
a slow turn-on resistor, wherein the slow turn-on switch is configured to selectively connect the slow turn-on resistor between the gate of the primary FET switching assembly and the auxiliary switching power supply;
a fast turn-on assembly comprising:
a fast turn-on switch; and
a fast turn-on resistor, wherein the fast turn-on switch is configured to selectively connect the fast turn-on resistor between the gate of the primary FET switching assembly and the auxiliary switching power supply; wherein the fast turn-on resistor has a resistance value that is smaller than that of the slow turn-on resistor;
a control circuit configured to:
regulate a rate at which the primary FET switching assembly conducting current from the primary inductor assembly turns off by selectively operating the slow shunt assembly and the fast shunt assembly; and
to regulate a rate at which the primary FET switching assembly conducting current from the primary inductor assembly turns on by selectively operating the slow turn-on assembly and the fast turn-on assembly.

13. The switching control system of claim 12, wherein:
the fast shunt resistor and the fast turn-on resistor each has a value of approximately 0.1 miliohms; and
the slow shunt resistor and the slow turn-on resistor each has a value of approximately 1 ohm.

14. The switching control system of claim 12, wherein the control circuit is operable to:
close the fast shunt switch during a first time interval to drive the primary FET switching assembly toward an off state at a fast rate;
open the fast shunt switch and close the slow shunt switch during a second time interval to drive the primary FET switching assembly toward an off state at a slower rate; and
close the fast shunt switch during a third time interval to drive the primary FET switching assembly to an off state at a fast rate.

15. The switching control system of claim 14, further including a timing circuit, wherein:
a duration of the first time interval, a duration of the second time interval, and a duration of a third time interval are determined by the timing circuit.

16. The switching control system of claim 15, wherein the duration of the first time interval is set to be approximately 8 nanoseconds.

17. The switching control system of claim 14, further including a current monitoring system, wherein:
the current monitoring system is configured to measure a current flowing through the primary FET switching assembly; and
the control circuit is further configured to set a duration of the first time interval, a duration of the second time interval, and a duration of a third time interval based on measurements of the current monitoring system.

18. The switching control system of claim 12, wherein the control circuit is further operable to:
close the fast turn-on switch during a first turn-on time interval to drive the primary FET switching assembly toward an on state at a fast rate;
open the fast turn-on switch and close the slow turn-on switch during a second turn-on time interval to drive the primary FET switching assembly toward an on state at a slower rate; and
close the fast turn-on switch during a third turn-on time interval to drive the primary FET switching assembly to an on state at a fast rate.

19. In a power conversion system comprising an input interface to a primary power source, an output interface to a load, a primary inductor assembly operatively connected between the input interface to the primary power source and the output interface to the load, a primary FET switching assembly operatively connected to the primary inductor assembly and configured to regulate the power delivered to the load; and a shunt control assembly operable to control the primary FET switching assembly, wherein the shunt control assembly includes a fast shunt switch and a slow shunt switch, a method of controlling a rate at which the primary FET switching assembly turns off comprises the steps of:
closing the fast shunt switch during a first time interval to cause the primary FET switching assembly to move toward an off state at a fast rate;
closing the slow shunt switch and opening the fast shunt switch during a second time interval to cause the primary FET switching assembly to move toward an off state at a slower rate; and
closing the fast shunt switch during a third time interval to cause the primary FET switching assembly to move toward the off state at a fast rate.

20. The method of claim 19, further comprising the steps of:
setting a pre-defined time duration of the first time interval;
setting a pre-defined time duration of the second time interval; and
setting a pre-defined time duration of the third time interval.

21. The method of claim 19, further comprising:
measuring a current flowing through the primary FET switching assembly;
defining a duration of the first time interval based on a measurement of the current flowing through the primary FET switching assembly;
defining a duration of the second time interval based on a measurement of the current flowing through the primary FET switching assembly; and
defining a duration of the third time interval based on a measurement of the current flowing through the primary FET switching assembly;
